(19) United States
(12) Patent Application Publication
(10) Pub. No.: US 2004/0149683 A1
(43) Pub. Date: Aug. 5, 2004

(54) Method for forming pattern using printing process

(75) Inventors: Myoung-Kee Baek, Kyonggi-do (KR); Kwon-Shik Park, Seoul (KR)

Correspondence Address: MORGAN LEWIS & BOCKIUS LLP, 1111 PENNSYLVANIA AVENUE NW, WASHINGTON, DC, 20004, US

(73) Assignee: LG.Philips LCD Co., Ltd.

(21) Appl. No.: 10/674,017

(22) Filed: Sep. 30, 2003

(30) Foreign Application Priority Data
Dec. 27, 2002 (KR) P2002-085628

(51) Int. Cl. C30B 33/00

(52) U.S. Cl. 216/23

(57) ABSTRACT

A method for forming a pattern using a printing process is disclosed in the present invention. The method includes providing a substrate having an etching layer formed thereon, locating a master having at least one opening in the etching layer, filling a resist in the at least one opening of the master, and separating the master from the substrate to leave the resist on the substrate.

This application claims the benefit of the Korean Patent Application No. P2002-085628 filed on Dec. 27, 2002, which is hereby incorporated by reference.

### BACKGROUND OF THE INVENTION

1. Field of the Invention

The present invention relates to a liquid crystal display device, and more particularly, to a method for forming a pattern in a liquid crystal display device. Although the present invention is suitable for a wide scope of applications, it is particularly suitable for improving fabrication productivity as well as forming a precise pattern.

2. Discussion of the Related Art

In display devices, particularly in flat panel display devices, pixels are arranged in a matrix form. Among the flat panel devices, liquid crystal display (LCD) devices have active devices, such as thin film transistors (hereinafter, TFTs), which are positioned in respective pixels for driving the pixels in the display devices. Such a method of driving the display device is called an active matrix driving method because the active devices are arranged in the respective pixels aligned in a matrix form.

FIG. 1 is a plane view of a pixel in the related art LCD device using the active matrix method. The active device is a TFT 10. As shown in FIG. 1, a plurality of gate lines 2 arranged horizontally and a plurality of data lines 4 arranged vertically define a pixel. The TFT 10 for independently controlling the driving of the respective pixel is formed near the intersection of each of the gate lines and each of the data lines. The TFT 10 includes a gate electrode 2a connected to one of the gate lines 2, a semiconductor 5 formed on the gate electrode 2a, and source and drain electrodes 4a and 4b formed on the semiconductor layer 5. The TFT 10 is activated when a scan signal is applied to the gate electrode 2a by one of the gate lines 2. At the pixel, a pixel electrode 7, which is connected to the drain electrodes 4b, is supplied with an image signal through the source and drain electrodes 4a and 4b, when the semiconductor layer 5 is activated by the gate electrode 2a. The pixel electrode 7 is connected to the drain electrode 4b through a first contact hole 8a. A storage line 6 and a storage electrode 11, which overlaps the storage line 6, are positioned in the pixel defined by the gate line 2 and the data line 4 to form a storage capacitor Cst. The storage electrode 11 is connected to the pixel electrode 7 through a second contact hole 8b.

FIG. 2 is a cross-sectional view taken along line I-I of FIG. 1 showing a TFT 10 and a storage capacitor Cst positioned inside the pixel. As shown in FIG. 2, the TFT 10 includes a substrate 1 formed of a transparent insulating material, such as glass, a gate electrode 2a formed on the substrate 1, a gate insulating layer 13 deposited over the entire substrate 1, a semiconductor layer 5 formed on the gate insulating layer 13, source/drain electrodes 4a and 4b formed on the semiconductor layer 5, a passivation layer 15 formed on the source/drain electrodes 4a and 4b to protect the device, and a pixel electrode 7 connected to the drain electrode 4b through the first contact hole 8a.

The storage capacitor Cst includes a storage line 6 formed at the same series of patterning processes as the gate electrode 2a of the TFT, and a storage electrode 11 formed at the same series of patterning processes as the source and drain electrodes 4a and 4b. A gate insulating layer 13 is formed between the storage line 6 and the storage electrode 11. A second contact hole 8b for exposing a portion of the storage electrode 11 is formed in the passivation layer 15. The storage electrode 11 is electrically connected to the pixel electrode 7 through the second contact hole 8b. The storage capacitor Cst charges through a gate voltage while a gate signal is applied to the gate electrode 2a, and then holds charges until the gate electrode 2 is selected in the next frame to prevent the voltage change of the pixel electrode 7. Herein, the sizes of the first and second contact holes 8a and 8b for electrically connecting the drain electrode 4b and the storage electrode 11 to the pixel electrode 7 are a few micrometers (μm), respectively.

The above-described LCD device is fabricated by a photo mask process, and the photo mask process includes a series of processes such as photoresist application, arrangement and exposure, development, cleaning, etc. Especially, in the exposure process, processes of disposing the mask on an original position, aligning the mask and the substrate as matching align keys of the mask and the substrate, and radiating a light source are proceeded in order. Herein, it is difficult to form an accurate alignment due to a limitation of the exposing equipment. Therefore, there is a limit in forming a fine pattern requiring a high degree of accuracy, and a plurality of photo processes should be repeated, thereby decreasing the productivity.

### SUMMARY OF THE INVENTION

Accordingly, the present invention is directed to a method for forming a pattern using a printing process that substantially obviates one or more of problems due to limitations and disadvantages of the related art.

Another object of the present invention is to provide a method for forming a pattern on a liquid crystal display device with a single process in a printing method.

A further object of the present invention is to provide a method for forming a pattern that simplifies equipment and forms a precise pattern by applying a direct contact or micro contact printing method using a master.

Additional features and advantages of the invention will be set forth in the description which follows and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a method for forming a pattern over a substrate includes providing a substrate having an etching layer formed thereon, locating a master having at least one opening in the etching layer, filling a resist in the at least one opening of the master, and separating the master from the substrate to leave the resist on the substrate.

In another aspect of the present invention, a method for forming a pattern over a substrate includes providing a substrate having an etching layer formed thereon, placing a master having at least one opening on an area corresponding to the etching layer to be etched, applying a resist on the master, planarizing the applied resist on the surface of the master and filling the resist in the at least one opening by using a doctor blade, hardening the planarized resist, and forming a resist pattern on the etching layer by separating the master from the substrate.

In a further aspect of the present invention, a method for forming a pattern over a substrate includes providing a substrate having an etching layer formed thereon, placing a master having at least one opening corresponding to the etching layer to be etched, contacting a resist supplying roll on the master to fill the resist in the at least one opening of the master, hardening the filled resist in the at least one opening of the master, and forming a resist pattern on the etching layer by separating the master from the substrate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention.

In the drawings:

FIG. 1 is a plane view illustrating a structure of the related art liquid crystal display device;

FIG. 2 is a cross-sectional view taken along line I-I illustrating structures of a thin film transistor and a storage capacitor of the liquid crystal display device showing in FIG. 1;

FIGS. 3A to 3C are cross-sectional views illustrating the process for forming a pattern using a gravure offset printing method according to a first embodiment of the present invention;

FIGS. 4A to 4C are views illustrating the process for forming a pattern in a direct contact printing method according to a second embodiment of the present invention; and

FIGS. 5A to 5C are views illustrating the process for forming a pattern in a micro contact printing method according to a third embodiment of the present invention.

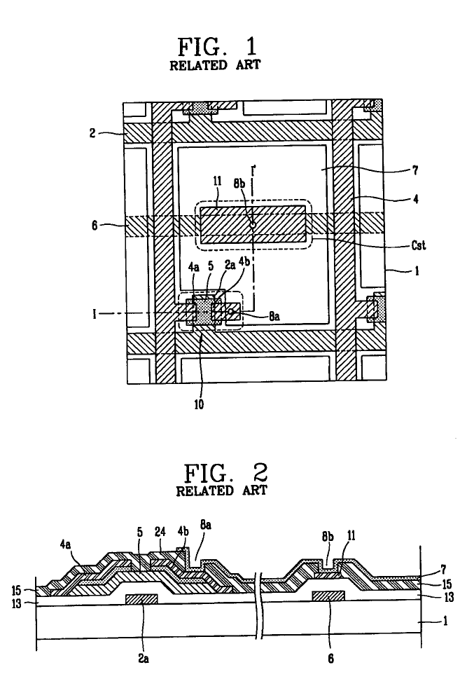

### DETAILED DESCRIPTION OF THE PREFERRED EMBODIMENTS

Reference will now be made in detail to the preferred embodiments of the present invention, examples of which are illustrated in the accompanying drawings. Wherever possible, the same reference numbers will be used throughout the drawings to refer to the same or like parts.

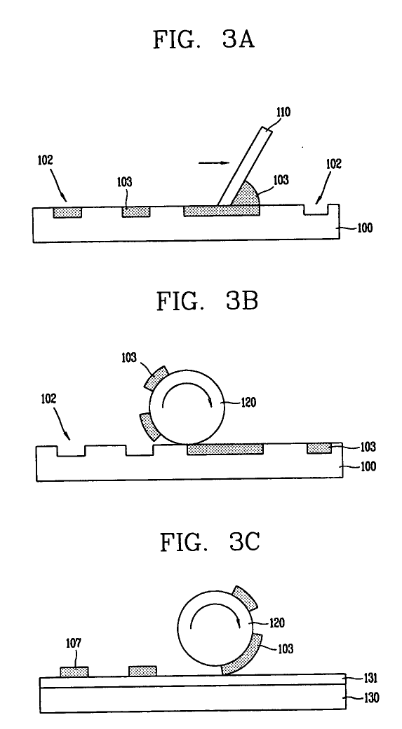

FIGS. 3A to 3C are cross-sectional views illustrating the process for forming a resist pattern on a substrate by using a printing method according to a first embodiment of the present invention.

As shown in FIG. 3A, a cliché 100, in which grooves 102 are formed in shapes and positions corresponding to a pattern to be formed on a substrate, is prepared, and a resist 103 is filled into the cliché 100. For example, an excess amount of a resist 103 is deposited on the surface of the cliché 100 and is pulled into the grooves 102 by a doctor blade 110 to planarize the resist 103 into the grooves, thereby removing the remaining resist. The doctor blade 110 should be pulled in the direction that is along the longest length of the groove. Otherwise, if the doctor blade 110 is pulled in the direction perpendicular or not parallel to the longest length of the groove, the resist may not fill the groove 102 smoothly along its longest length such that subsequent processes can remove the resist from the cliché 100.

As shown in FIG. 3B, the resist 103 filled in the groove 102 of the cliché 100 is transferred on the surface of the rotating printing roll 120 when the printing roll 120 is rolled across the surface of the cliché 100. The printing roll 120 has the same width as that of the panel of the display device to be fabricated. Further, the printing roll has the circumference identical to the length of the panel of the display device to be fabricated. Therefore, the resist 103 filled into the groove 102 of the cliché 100 is transferred onto the circumferential surface of the printing roll 120.

As shown in FIG. 3C, the printing roll 120 with the resist 103 on the circumferential surface is rolled on the surface of an etching layer 131 formed on a substrate 130 to apply the resist 103 to the etching layer 131, and a resist pattern 107 is formed by drying the applied resist 103 with a scanning UV light or applying heat. The pattern 107 necessary for the entire patterning process step for the etching layer can be formed over the entire substrate 120 of the display device by rotating the printing roll 120 on the etching layer 131. Accordingly, since the cliché 100 and the printing roll 120 can be fabricated according to the size of the preferable display device and the pattern can be formed on the substrate 130 by one application, the patterning of a large-area display device for an etching layer can be performed in a single series of patterning processes.

The etching layer 131 can be formed of a metal layer for forming a metal pattern, such as gate electrodes of TFTs and storage electrodes. In another example, the metal layer can be for forming source/drain electrodes, gate lines and data lines. Alternatively, the etching layer can be formed of an insulating layer, such as SiOₓ or SiNₓ, or a semiconductor layer.

After forming the resist pattern 107 on the metal layer or the insulating layer, the metal layer or the insulating layer is etched through a common etching process, thereby forming a desired pattern layer, more specifically, in the case of a metal layer (i.e., an electrode structure) or the insulating layer (e.g., a contact hole).

The resist pattern can be formed by using the above printing method with a single process, and especially, the processes are simple and the processing time can be reduced as compared to the related art photo mask process.

However, the method for forming the pattern in the gravure offset printing method has a disadvantage in that an interface characteristic between the etching layer and the resist pattern is inferior. That is, when the resist is transferred from the cliché 100 to the printing roll 120, the resist is not separated smoothly from the recess 102, and therefore, some of the resist remain on the recess 102 and the surface of the resist transferred on the printing roll 120 is not even. Therefore, a gap may be generated on the interface between the substrate 120 and the resist pattern when the resist is re-transferred to the substrate 120. As described above, in case that the gap is generated on the interface, the etchant is leaked into the gap when the pattern is formed by etching the etching layer 131 by the etching process, and therefore, an undesired portion of the etching layer 131 is etched to cause a deficiency in the product.

Also, according to the above printing method, the resist filled in the cliché 100 is not transferred directly to the substrate 130, but the processes of transferring the resist on the printing roll 120 and applying the resist to the substrate are carried out. Therefore, there is a limit in forming a precise pattern of high precision.

In order to resolve such problems, the present invention provides a method for forming a pattern which is able to form a fine pattern of high precision by forming a patterned resist directly on the substrate using a master on which an opening is partially formed.

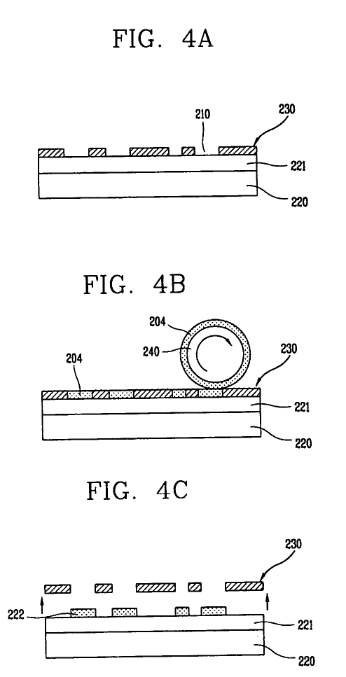

FIGS. 4A to 4C are cross-sectional views illustrating the process for forming a pattern using a direct contact printing method according to a second embodiment of the present invention. As shown in FIG. 4A, an etching layer 221 is formed on a substrate 220, and a master 230 is contacted thereon. In this process, an opening 210 is selectively formed in the master 230, and corresponds to a pattern area of the etching layer 221, which will be formed in later processes. Then, as shown in FIG. 4B, a resist supplying roll 240 is contacted to the master 230. The roll 240 is then rotated to fill the resist 204 in the opening 210. The resist 204 is applied on the opening 210 and the surface of the master 230, the doctor blade (not shown) is contacted to the master 230 and pushed to planarize the surface, thereby filling the resist 204 only in the opening 210 and removing the resist applied on the master 230.

As described above, after filling the resist 104 having the same thickness in the opening 210 of the master 230, the UV-ray or heat is radiated to dry the resist 204, as shown in FIG. 4C. Then, the master 230 is separated from the substrate 220 to form a resist pattern 222. In this process, since the shape of the resist pattern 222 is changed when the master 230 is shaken, the master 230 is handled with care so as to prevent the shaking of the master 230.

In the direct contact printing method, the resist pattern is directly formed on the substrate without a transferring process of the resist. Therefore, the interface characteristic between the substrate and the resist is superior, and the pattern of high precision can be formed accurately.

However, in case that the etching layer 221 has a stepped portion due to the lower layer, the substrate is damaged when the master is directly contacted to the etching layer 221. Therefore, when the surface of the etching layer 221 has the stepped portion, the micro contact printing method does not directly contact the master to the substrate, but disposes the master with a few micrometers (μm) gap.

The micro contact printing method has a similar pattern forming method as that of the direct contact printing method, except for a difference in that the master is separated from the substrate by a few micrometers (μm).

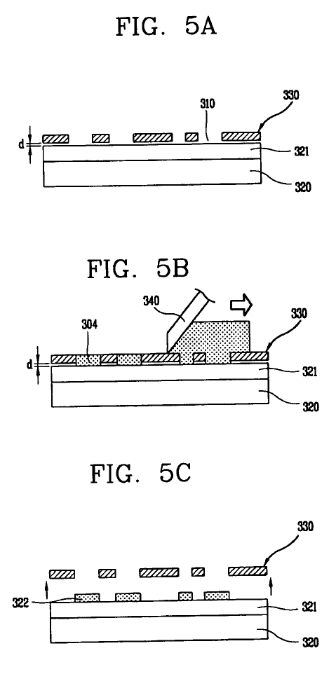

FIGS. 5A to 5C are cross-sectional views illustrating the process for forming a pattern using the above micro contact printing method. As shown in FIG. 5A, a substrate 320 having an etching layer 321 formed thereon is provided, and then, a master 330 having an opening 310 formed on an area corresponding to the position where the pattern will be formed is disposed on a position spaced apart from the substrate 320 as far as distance d. Herein, the distance is a few micrometers (μm), and the master 330 is disposed in parallel with the substrate. Next, as shown in FIG. 5B, the resist 304 is filled in the opening 310 and in the separating area connected to the opening 310. The filling method of the resist is the same as that of the second embodiment. A method for applying the resist 304 on the master 330 in advance and a method for planarizing the resist with the doctor blade 340 are shown in FIG. 5A. At that time, a metal precursor such as a silver (Ag) paste or a conductive polymer may be used instead of the resist. Thereafter, as shown in FIG. 5C, UV-rays or heat is radiated to dry the resist, and then, the master 330 is separated from the substrate 320 to form the resist pattern 322. Next, the etching layer 321 is etched using the resist pattern 322 as a mask to form a desired pattern. For example, when the etching layer 321 is a metal layer, all metal layers forming the liquid crystal display device, such as the gate electrode, the gate line, source/drain electrodes, the data line and the pixel electrode, etc., are formed. In addition, when the etching layer is an inorganic layer, such as SiOₓ or SiNₓ, or an organic layer such as BCB, a contact hole is formed. Alternatively, the etching layer may be a semiconductor layer.

In the micro contact printing method, the master is not directly contacted to the substrate, thereby reducing contamination of the substrate as compared to the direct contact printing method. That is, even if the master is thoroughly cleaned before the printing process, the impurities are remained on the surface of the master, thereby contaminating the substrate. However, when the master is separated from the substrate, the contamination of the substrate can be prevented.

As described above, according to the present invention, the resist pattern is formed in one printing process to simplify the processing equipment and to reduce the processing time and cost, thereby improving process efficiency. Also, according to the present invention, the resist pattern is directly formed on the substrate without using the printing roll, and therefore, the pattern of high precision can be formed accurately.

It will be apparent to those skilled in the art that various modifications and variations can be made in the method for forming the pattern using the printing process of the present invention without departing from the spirit or scope of the inventions. Thus, it is intended that the present invention covers the modifications and variations of this invention provided they come within the scope of the appended claims and their equivalents.

What is claimed is:

1. A method for forming a pattern over a substrate, comprising:
providing a substrate having an etching layer formed thereon;
locating a master having at least one opening in the etching layer;
filling a resist in the at least one opening of the master; and
separating the master from the substrate to leave the resist on the substrate.

2. The method of claim 1, wherein the filling a resist in the at least one opening of the master comprises:
contacting a resist supplying roll to the master; and
filling the resist in the at least one opening of the master by rotating the resist supplying roll over the at least one opening of the master.

3. The method of claim 1, wherein the filling a resist in the at least one opening of the master comprises:
applying the resist on the master; and
planarizing the applied resist on the surface of the master by using a doctor blade.

4. The method of claim 1, wherein the master is separated apart from the substrate by a few micrometers (μm).

5. The method of claim 1, wherein the etching layer is a metal layer.

6. The method of claim 1, wherein the etching layer is an insulating layer.

7. The method of claim 6, wherein the insulating layer is formed of one of SiOₓ or SiNₓ.

8. The method of claim 1, wherein the etching layer is a semiconductor layer.

9. The method of claim 1, further comprising hardening the resist.

10. A method for forming a pattern over a substrate, comprising:
providing a substrate having an etching layer formed thereon;
placing a master having at least one opening on an area corresponding to the etching layer to be etched;
applying a resist on the master;
planarizing the applied resist on the surface of the master and filling the resist in the at least one opening by using a doctor blade;
hardening the planarized resist; and
forming a resist pattern on the etching layer by separating the master from the substrate.

11. The method of claim 10, wherein the master is separated apart from the substrate by a few micrometers (μm).

12. A method for forming a pattern over a substrate, comprising:
providing a substrate having an etching layer formed thereon;
placing a master having at least one opening corresponding to the etching layer to be etched;
contacting a resist supplying roll on the master to fill the resist in the at least one opening of the master;
hardening the filled resist in the at least one opening of the master; and
forming a resist pattern on the etching layer by separating the master from the substrate.

13. The method of claim 12, wherein the master is separated apart from the substrate by a few micrometers (μm).
